(19) United States
(12) Patent Application Publication
(10) Pub. No.: US 2005/0034749 A1
(43) Pub. Date: Feb. 17, 2005

(54) Structure of thermopile sensor

(76) Inventors: Chung-Nan Chen, Sindian City (TW); Hung-Te Lin, Fongshan City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 10/638,348

(22) Filed: Aug. 12, 2003

(51) Int. Cl. H01L 35/28

(52) U.S. Cl. 136/224

(57) ABSTRACT

The invention relates to an improved structure of a thermopile sensor, which is to employ a membrane to cover a substrate that has a cavity. Besides, a plurality of thermoelectric elements is formed on the membrane extending outwards from the central side of the membrane and is composed of two different materials connected in series. The material of the element can be a composite of metal material and semiconductor material, and an insulation layer partitions the two materials; therefore, the two materials are connected in series through a contact hole. In addition, the contact hole formed at the central side of the membrane is called hot junction, whereas the contact hole formed at the side of the substrate is called cold junction. Moreover, to enhance the sensing performance of the thermopile sensor, a heat-conducting layer is formed at the center of the membrane, and after the heat-conducting layer is covered with another insulation layer, an absorption film is formed. The invention changes the temperature difference distribution by adding in a heat-conducting layer so as to enhance the sensing performance.

### BACKGROUND OF THE INVENTION

1. Field of the Invention

The invention relates to an improved structure of a thermopile sensor that enhances the sensing performance.

2. Description of the Related Art

A thermopile sensor device has been broadly applied to products such as ear thermometers, fire alarm devices, and smart house appliances for various functions. Technically, a thermopile infrared sensor is composed of thermocouples connected in series. Therefore, as long as there is temperature difference existing between the hot junctions and the cold junctions of the thermocouples, an output voltage signal that is very convenient for use can be generated. In recent years, with the advancement of semiconductor fabrication techniques, the techniques such as planar processing technique of the integrated circuit and anisotropic etching technique of the micro-electro-mechanical system (MEMS) are adopted for the fabrication of thermopile sensor device, which enables the fabrication of thermopiles to have the potentials of mass-production and integration.

A thermopile infrared sensor and the process of fabricating the same are disclosed in the U.S. Pat. No. 6,348,650. Like the structure of a typical thermopile sensor, the thermopile sensor 100 is located on the substrate 10 with a cavity 12 that contains a membrane 14 covering the cavity 12, as shown in FIG. 1. Besides, a plurality of thermoelectric elements that comprise the semiconductor layer 16 and the metal film 20 is provided on the membrane 14. In addition, a first insulation layer 18 is provided between the semiconductor layer 16 and the metal film 20. Also, a contact hole between the semiconductor layer 16 and the metal film 20 forms a hot junction 26 at the central side of the membrane 14 and a cold junction 28 at the side of the substrate 10 respectively. Moreover, by utilizing the metal film 20, a pre-arranged electrical connection between the hot junction 26 and the cold junction 28 is formed. By doing so, if a temperature difference occurs between the hot junction 26 and the cold junction 28, the output voltage signal can be generated to determine the temperature. Moreover, in order to generate a temperature difference between the hot junction 26 and the cold junction 28, an infrared absorption film 24 is provided on the thermoelectric elements through a second insulation layer 22. The temperature of the hot junction 26 is higher than that of the cold junction 28 because the hot junction 26 is covered with the infrared absorption film 24; therefore, a voltage signal can be generated to determine the temperature.

In general, the temperature measurement principle of the thermopile sensor is to employ an absorption film to absorb infrared radiation so that the thermoelectric elements can generate a voltage signal due to temperature difference between the hot junctions under the absorption film and the cold junctions at the side of the substrate. Also, the output voltage signal is to determine the temperature, and the output voltage is in direct ratio to the temperature difference between the hot junctions and the cold junctions; that is, the larger the temperature difference is, the more the voltage can be outputted. Therefore, suppose that the temperature to be measured remains unchanged and a larger temperature difference between the hot junctions and the cold junctions has been formed, the output voltage signal will become larger, which in turn can make better performance on the thermopile sensor. On the other hand, if a thermoelectric-element layer that connects the two junctions becomes longer, the generated resistance will become larger. However, the increased resistance will also increase the noise of the thermoelectric elements, which in turn will affect the performance of the whole thermoelectric elements.

Therefore, to enhance the performance of a conventional thermopile sensor, according to the technique disclosed in the aforementioned U.S. patent, the hot junction has to be closer to the center of the membrane so that the temperature difference between the hot junction and the cold junction can be increased. However, doing so means that the length of the thermoelectric-element layer will also be lengthened, which will increase the whole resistance connected in series and thus the noise of the device will increase as well. Therefore, the technique cannot effectively enhance the overall device performance.

In brief, a more rapid and accurate sensor is essential in many applications, but that is only one of the goals to be pursued. There are other goals, such us diminishing the dimension of the device, simplifying the fabrication flow, and controlling the cost effectively, to be achieved so that the developed product may have better performance and potential for mass production and low cost. Therefore, all these goals are for the invention to focus on so that the developed products may have an excellent performance without increasing the fabrication cost.

### SUMMARY OF THE INVENTION

The object of the invention is to provide an improved structure of a thermopile sensor to enhance the sensing performance.

Another object of the invention is to provide a thermopile sensor fabricated through the current technique so as to reduce the cost as well as increase the potential for mass production.

Focusing on the aforementioned objects, the invention provides an improved structure of a thermopile sensor, which includes a substrate with a cavity that is covered by a membrane. Besides, at least one thermoelectric element is provided on the membrane, and the thermoelectric element is composed of a first thermoelectric-element layer and a second thermoelectric-element layer. Also, an insulation layer is provided between the two thermoelectric-element layers, and the serial connection between the two is through a contact hole. Moreover, the contact hole formed at the central side of the membrane is called hot junction, whereas the one formed at the side of the substrate is called cold junction. In addition, a heat-conducting layer is provided at the center of the membrane, and a space is formed between the heat-conducting layer and the two thermoelectric-element layers. Then, an insulation layer is provided on the membrane, and an absorption film is provided on the insulation layer at the center of the membrane to cover the hot junction. The improved structure, with the basis of a conventional structure, absorbs infrared through the absorption film so that the hot junction and the cold junction can generate a temperature difference and output a voltage signal for sensing the temperature. Moreover, the invention adds in a heat-conducting layer to the center of the membrane to alter the temperature distribution and increase temperature difference between the hot junction and the cold junction so that the sensing performance can be enhanced. In addition, the improved structure will not increase the procedures and difficulties of fabrication. Hence, the product is suitable for mass production since the fabrication cost will not be increased.

### BRIEF DESCRIPTION OF THE DRAWINGS

FIG. 1 is a sectional schematic diagram of a conventional thermopile sensor.

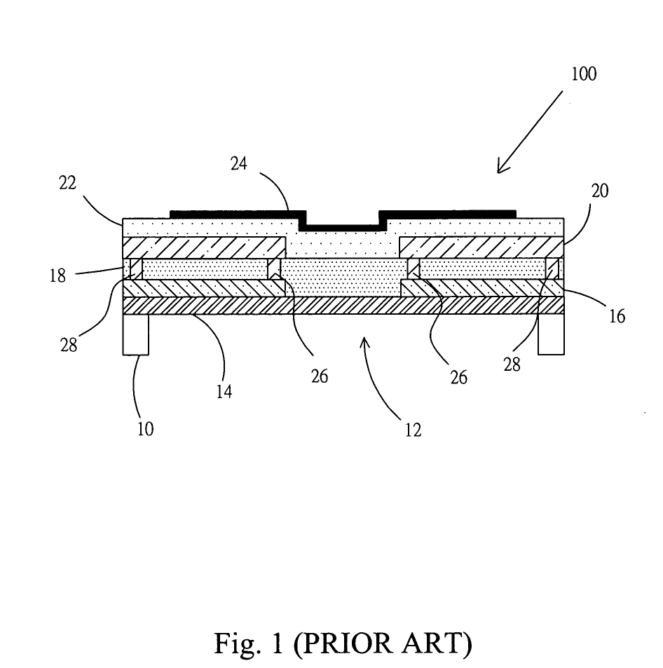

FIG. 2 is a sectional schematic diagram of the thermopile sensor of the invention.

FIG. 3 is a diagram showing temperature distribution of the thermopile sensor after through infrared radiation.

FIG. 4 is a sectional schematic diagram of one embodiment of the invention.

FIG. 5 is a sectional schematic diagram of another embodiment of the invention.

### DETAILED DESCRIPTION OF THE PREFERRED EMBODIMENTS

The invention is designed with a purpose in mind that the sensing performance should be enhanced without increasing the noise. Therefore, the invention improves the structure of a thermopile sensor on the basis of a conventional structure to achieve the above-mentioned purpose. The invention provides a heat-conducting structure at the center of a membrane to change the temperature distribution so that the temperature difference generated between the hot junctions and the cold junctions may become larger to enhance the sensing performance.

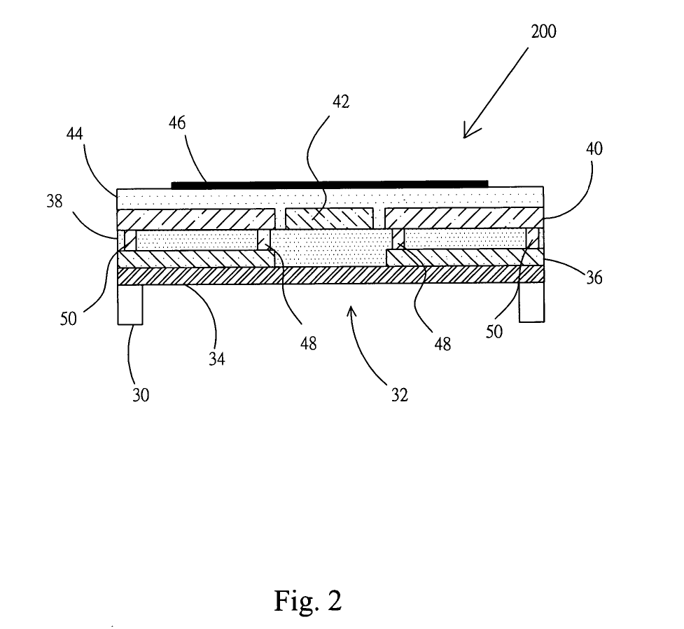

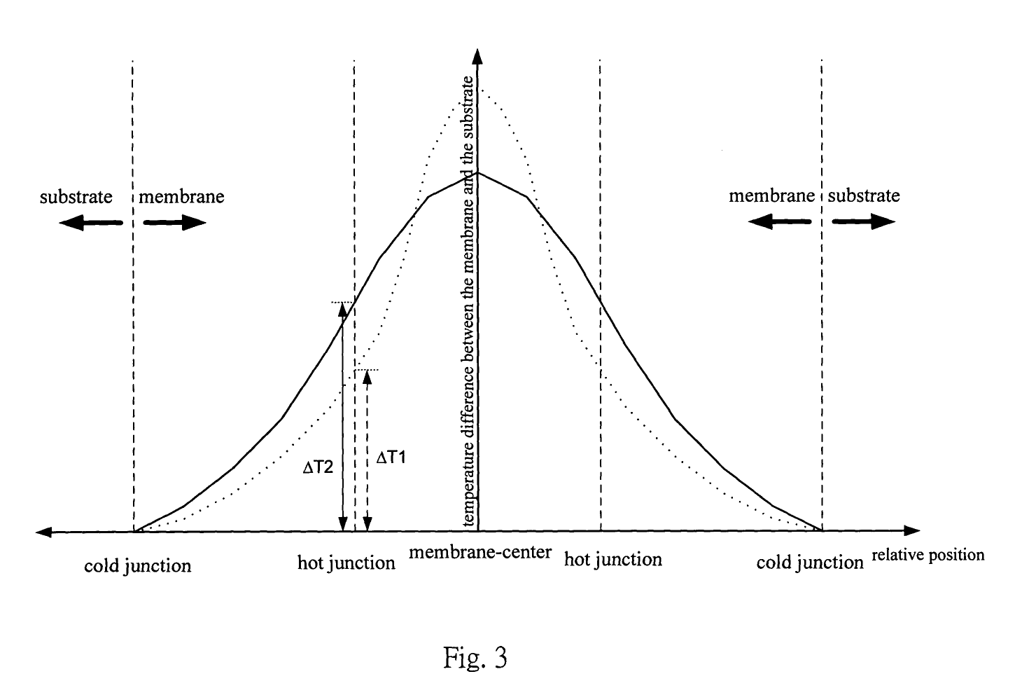

FIG. 2 is a schematic diagram showing an improved structure of the thermopile sensor 200 provided by the invention. The invention provides a single crystalline silicon substrate 30 and a cavity 32 that is a recess on the front side or backside of the substrate 30 formed by anisotropic etching. Besides, a membrane 34 covers the cavity 32, and the membrane 34 is composed of more than one layer of insulation film. Then, one or more than one thermoelectric element is provided on the membrane 34, while the thermoelectric element is composed of a first thermoelectric-element layer 36 and a second thermoelectric-element layer 40. In addition, a first insulation layer 38 is to cover the first thermoelectric-element layer 36, and the second thermoelectric-element layer 40 is provided on top of the first insulation layer 38. Moreover, a contact hole is provided between the second thermoelectric-element layer 40 and the first thermoelectric-element layer 36, allowing the two layers to be interactively connected in series. Specifically, the contact hole can be classified into a hot junction 48 and a cold junction 50. The hot junction 48 is provided at the central side of the membrane 34, whereas the cold junction 50 is provided at the side of the substrate 30. After radiation, the center of the membrane 34 will have the highest temperature of all the distributed temperatures, wherein the temperature distribution is in a manner that declines progressively from the center toward the periphery of the membrane. Therefore, if the temperature difference between the hot junction and the cold junction is to be increased, the hot junction 48 should be closer to the center of the membrane 34. However, doing so will have to lengthen the first thermoelectric-element layer 36 and the second thermoelectric-element layer 40 between the hot junction and the cold junction. Consequently, the noise will increase as well. To cope with the problem, the present invention provides a heat-conducting structure 42 at the center of the membrane 34, which allows the temperature distribution on the whole membrane 34 to be changed so that the temperature difference between the hot junction and the cold junction can be increased. FIG. 3 is a diagram showing temperature distribution of the thermopile sensor after through infrared radiation. Referring to FIG. 3, the axis of abscissa represents the relative position of each area of the sensor, whereas the axis of ordinate represents the temperature difference between the membrane 34 and the substrate 30. Besides, in FIG. 3, the dotted-line curve represents the temperature difference distribution of each area of a conventional sensor, whereas the bold-line curve represents the temperature difference distribution of each area of the sensor of the invention. When the infrared radiates on the sensor, the temperature difference between the central membrane and the substrate will become the largest because the heat-conducting effect of the central membrane is at its worst performance. On the other hand, if the membrane is doing without the heat-conducting structure 42 of the invention, the radiated heat at the central membrane cannot be conducted to the hot junction effectively, which in turn will make the temperature difference between the hot junction and the cold junction become smaller. Consequently, the outputted signal of the element will become smaller as well. Therefore, the heat-conducting structure of the invention can effectively conduct the radiated heat at the central membrane to the hot junction so that the temperature difference between the membrane and the cold junction of the substrate will become larger, thereby amplifying the outputting signal.

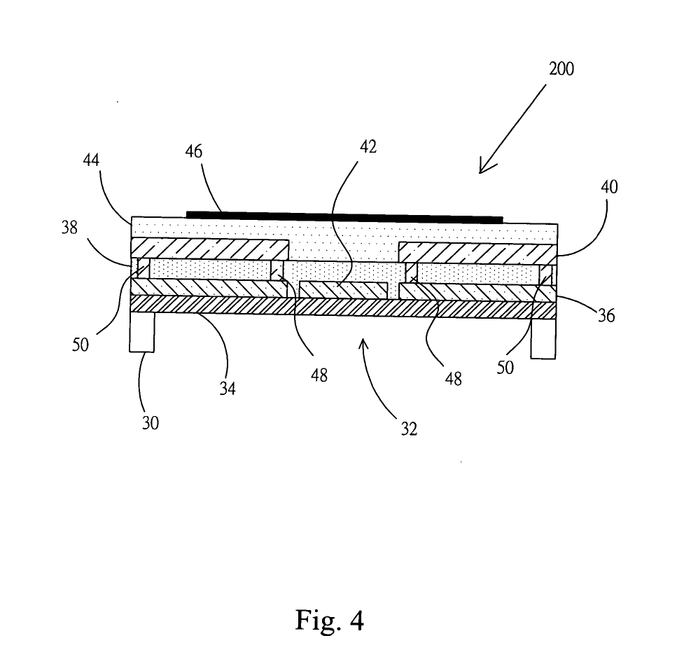

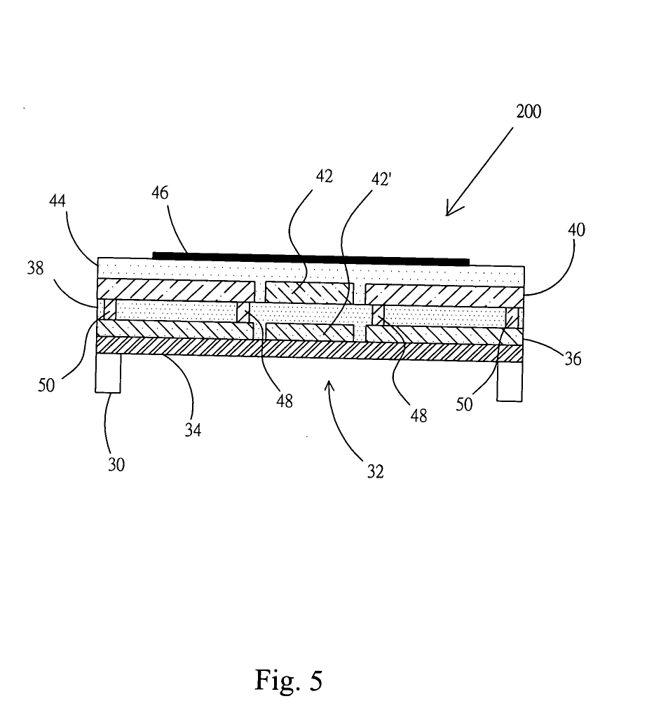

Also, referring to FIG. 2, there is no direct contact between the first thermoelectric-element layer 36 and the heat-conducting structure 42 due to the space between them. Likewise, neither will there be direct contact between the second thermoelectric-element layer 40 and the heat-conducting structure 42 due to the space between them. Therefore, the serial-connected resistance of the element will not be increased, and neither will the noise. Hence, as shown in FIG. 4, the heat-conducting structure 42 can be located on the membrane 34, or, alternatively, the heat-conducting structure 42 can be provided on both the membrane 34 and the first insulation layer 38, as shown in FIG. 5. In addition, the absorption film 46 for absorbing infrared is provided on top of the layer of the element through a second insulation layer 44, and the covering range of the absorption film 46 is to cover the hot junction 48 only, not including the cold junction 50. The material of the absorption film 46 can be either one of the following: borosilicate glass, polyimide resin, vinyl resin, or propenyl resin. On the other hand, the material of the second insulation layer 44 can be silica or silicon nitride.

Alternatively, in one embodiment of the invention, the material of the heat-conducting structure can be the same as that of the thermoelectric element. Besides, the heat-conducting structure can be generated concurrently with the thermoelectric element so as to prevent from increasing the procedures for fabrication. In addition, the material of the first thermoelectric-element layer and the second thermoelectric-element layer of the thermoelectric element can be composite materials of semiconductor and metal. On the other hand, either the semiconductor material or the metal material can be the only choice for both layers, or the choice may be that the metal material is for one of the thermoelectric-element layers whereas the semiconductor material is for the other one.

Through the improved structure of the thermopile sensor that provides a heat-conducting structure on the center of the membrane, not only can the temperature difference between the hot junction and the cold junction as well as the output voltage signal can be increased, but the noise of the element can also be prevented from increasing. On the other hand, the added-in heat-conducting structure can be generated concurrently while fabricating the thermoelectric elements. Therefore, the procedures and difficulties of fabrication can be avoided from increasing. Finally, compared to a conventional thermopile element, the improved structure of the invention can enhance the performance of the thermopile sensor without increasing the fabrication cost because the fabrication technique is based on the conventional technique. Therefore, in real application, the performance of the thermopile sensor provided by the invention can be excellent without adding any cost.

1. An improved structure of a thermopile sensor, including:
a substrate, having a cavity;
a membrane, covering the cavity;
a plurality of thermoelectric elements, formed on the membrane, wherein the thermoelectric element is composed of a first thermoelectric-element layer that extends outwardly from the central side of the membrane and a second thermoelectric-element layer formed above the first thermoelectric-element layer and is partitioned from the first thermoelectric-element layer by an insulation layer, and the first thermoelectric-element layer and the second thermoelectric-element layer is connected in series through a contact hole that forms a hot junction at the central side of the membrane and a cold junction at the side of the substrate;
a heat-conducting layer, formed at the center of the membrane, wherein a space is formed between the heat-conducting layer and the first thermoelectric-element layer, and a space is also formed between the heat-conducting layer and the second thermoelectric-element layer;
a second insulation layer, formed above the thermoelectric element and the heat-conducting layer; and
an absorption film, formed on the second insulation layer and used for covering the hot junction.

2. The improved structure of a thermopile sensor as claimed in claim 1, wherein the substrate is a single crystalline silicon substrate.

3. The improved structure of a thermopile sensor as claimed in claim 1, wherein the membrane is an insulation structure composed of more than one layer of thin film.

4. The improved structure of a thermopile sensor as claimed in claim 1, wherein the heat-conducting layer is formed on top of the membrane.

5. The improved structure of a thermopile sensor as claimed in claim 1, wherein the heat-conducting layer is formed on top of the first insulation layer.

6. The improved structure of a thermopile sensor as claimed in claim 1, wherein the heat-conducting layer is concurrently formed on the membrane and the first insulation layer.

7. The improved structure of a thermopile sensor as claimed in claim 1, wherein the first thermoelectric-element layer is made of semiconductor material.

8. The improved structure of a thermopile sensor as claimed in claim 1, wherein the first thermoelectric-element layer is made of metal material.

9. The improved structure of a thermopile sensor as claimed in claim 1, wherein the second thermoelectric-element layer is made of semiconductor material.

10. The improved structure of a thermopile sensor as claimed in claim 1, wherein the second thermoelectric-element layer is made of metal material.

11. The improved structure of a thermopile sensor as claimed in claim 1, wherein the material of the heat-conducting layer is the same as that of the first thermoelectric element.

12. The improved structure of a thermopile sensor as claimed in claim 1, wherein the material of the heat-conducting layer is the same as that of the second thermoelectric element.

13. The improved structure of a thermopile sensor as claimed in claim 1, wherein the second insulation layer is made of more than one layer of insulation material, which can be silica or silicon nitride.

14. The improved structure of a thermopile sensor as claimed in claim 1, wherein the absorption film is an infrared absorption film.

15. The improved structure of a thermopile sensor as claimed in claim 14, wherein the infrared absorption film is composed of either of the following: borosilicate glass, polyimide resin, vinyl resin, or propenyl resin.

16. The improved structure of a thermopile sensor as claimed in claim 1, wherein the cavity of the substrate is formed on the front side of the substrate by anisotropic etching.

17. The improved structure of a thermopile sensor as claimed in claim 1, wherein the cavity of the substrate is formed on the backside of the substrate by anisotropic etching.
